(19) United States
(12) Patent Application Publication
(10) Pub. No.: US 2025/0132286 A1
(43) Pub. Date: Apr. 24, 2025

(54) SEMICONDUCTOR PACKAGING METHOD, SEMICONDUCTOR ASSEMBLY COMPONENT AND ELECTRONIC DEVICE

(71) Applicant: Yibu Semiconductor Co., Ltd., Shanghai (CN)

(72) Inventor: Wenqi Li, Shanghai (CN)

(73) Assignee: Yibu Semiconductor Co., Ltd., Shanghai (CN)

(21) Appl. No.: 18/920,839

(22) Filed: Oct. 18, 2024

(30) Foreign Application Priority Data
Oct. 18, 2023 (CN) 202311352811.3

(51) Int. Cl. H01L 23/00; H01L 21/3105; H01L 21/56; H01L 21/683; H01L 25/065

(52) U.S. Cl. CPC H01L 24/81; H01L 21/31051; H01L 21/565; H01L 21/6835; H01L 24/03; H01L 24/95; H01L 25/0655; H01L 2224/03614; H01L 2224/03622; H01L 2224/81143; H01L 2224/81203; H01L 2224/81801; H01L 2224/95001; H01L 2224/95143; H01L 2924/37001

(57) ABSTRACT

The invention relates to a semiconductor packaging method, a semiconductor assembly and electronic device. In some embodiments, alignment solder bumps and alignment bonding pads are subjected to fusion bonding, in which the surface tension generated by the alignment solder bumps in a fusion state automatically pulls a semiconductor device to a target position on a carrier, and accurately fixes the semiconductor device at the target position. Thus, the semiconductor device is prevented from drifting and rotating in a molding process, and the yield of subsequent processing can be effectively improved. Further, the requirement on the precision of placing the semiconductor device on the carrier is reduced, greatly simplifying and speeding-up picking and placing operations. In addition, an active surface of the semiconductor device are pre-sealed to avoid height restriction of connecting terminals thereon, improve the chemical resistance of the connecting terminals, and protect the reliability of the active surface.

### CROSS REFERENCE TO RELATED APPLICATION

The present application claims the benefit of priority under the Paris Convention to Chinese Patent Application No. 202311352811.3, filed on Oct. 18, 2023, which is incorporated herein by reference in its entirety. This application is related to co-pending US Patent Application entitled “Semiconductor packaging method, semiconductor assembly component and electronic device,” filed on even date herewith (Attorney Docket No. YB029-11US), which is incorporated herein by reference in its entirety.

### TECHNICAL FIELD

The disclosure relates to the field of semiconductor technology, and in particular to a semiconductor packaging method, a semiconductor assembly component and an electronic device.

### BACKGROUND

Semiconductor packaging and systems have been pursued to be compact, small, light, thin in design, while achieving high integration and versatility in functional aspects. Various packaging techniques are currently proposed to meet the above requirements, such as Fan-out Wafer Level packaging, chiplet packaging, heterogeneous integration, 2.5D/3D packaging.

Taking fan-out packaging as an example, the main technical problem it faces is that there is still a lack of efficient and economical methods for high-precision placement and position fixation of chips. In related technologies, fan-out packaging mostly uses expensive placement machines for placement, which have high equipment costs, slow placement speed, and low positioning accuracy. It mainly depends on the accuracy of the placement machine, which has become a major bottleneck in the development and popularization of technology.

### SUMMARY

In order to solve the technical problems, the present disclosure provides a semiconductor packaging method, a semiconductor assembly component and an electronic device.

In the first aspect, the present disclosure provides a semiconductor packaging method, comprising:

Providing a semiconductor device; the semiconductor device comprises an active surface and a passive surface which are oppositely arranged, wherein the passive surface comprises alignment bonding pads, and the active surface is provided with a protective film;

Removing the protective film, and forming connecting terminals on the active surface;

Providing a carrier; the surface of one side of the carrier is provided with alignment solder bumps corresponding to the alignment bonding pads;

The alignment solder bumps are basically aligned with the alignment bonding pads, and fusion bonding is carried out on the alignment solder bumps and the alignment bonding pads, so that the semiconductor device is accurately aligned and fixed to the carrier;

Forming a molding layer on one side of the carrier facing the semiconductor device; the molding layer covers the semiconductor device, also covers the active surface, the connecting terminals and the surface of one side of the carrier, which is not occupied by the semiconductor device, and is filled in the gap between the semiconductor device and the carrier.

In some embodiments, before the providing the semiconductor device, the semiconductor packaging method further includes:

Forming the protective film on the active surface;

Forming the alignment bonding pads on the passive surface.

In some embodiments, the forming alignment bonding pads on the passive surface includes:

Forming a first metal layer on the passive surface;

Forming a patterned first photoresist layer on one side of the first metal layer away from the semiconductor device; the first photoresist layer comprises second openings, and the first openings exposes the first metal layer;

Etching the first metal layer exposed by the first openings based on the patterned first photoresist;

Removing the first photoresist layer to expose the alignment bonding pads.

In some embodiments, before the providing the carrier, the semiconductor packaging method further includes:

Forming a second metal layer on one side of the carrier;

Forming a patterned second photoresist layer on one side of the second metal layer away from the carrier; the second photoresist layer comprises second openings, and the second openings exposes the second metal layer;

Etching the metal layer exposed by the second openings based on the second photoresist to form a bonding pads;

Removing the second photoresist to expose the bonding pads;

Forming alignment solder bumps on one side of the bonding pads, which is away from the carrier.

In some embodiments, the performing fusion bonding on the alignment solder bumps and the alignment bonding pads includes:

Heating the alignment solder bumps so that the alignment solder bumps is at least partially in a molten state;

Bonding the alignment solder bumps which are at least partially in a molten state with the alignment bonding pads.

In some embodiments, the semiconductor packaging method further includes:

The carrier is removed using at least one of lift-off, etching, ablation, and grinding processes.

In some embodiments, after removing the carrier, the semiconductor packaging method further includes:

Thinning the surface of the molding layer, which is close to one side of the alignment solder bumps.

In some embodiments, the semiconductor packaging method further includes:

Thinning the surface of the molding layer, which is close to the active surface and one side of the connecting terminals, so as to expose the connecting terminals;

Forming an interconnection layer and external terminals on the surface of one side of the molding layer, which is exposed from the connection terminals; the connection terminals are electrically connected with the external terminals through the interconnection layer.

In the second aspect, the present disclosure also provides a semiconductor assembly packaged by any one of the above semiconductor packaging methods.

In the third aspect, the present disclosure also provides an electronic device, including: the semiconductor assembly.

Compared with the prior technology, the technical scheme provided by the disclosure has the following advantages:

The present disclosure provides a semiconductor packaging method, a semiconductor assembly, and an electronic device, the semiconductor packaging method including: providing a semiconductor device; the semiconductor device comprises an active surface and a passive surface which are oppositely arranged, wherein the passive surface comprises alignment bonding pads, and the active surface is provided with a protective film; removing the protective film, and forming connecting terminals on the active surface; providing a carrier; the surface of one side of the carrier is provided with alignment solder bumps corresponding to the alignment bonding pads; the alignment solder bumps and the alignment bonding pads are basically aligned, and fusion bonding is carried out on the alignment solder bumps and the alignment bonding pads, so that the semiconductor device is accurately aligned and fixed to the carrier; forming a molding layer on one side of the carrier facing the semiconductor device; the molding layer is used for coating the semiconductor device, also covers the active surface, the connecting terminals and the surface, which is not occupied by the semiconductor device, of the surface of one side of the carrier facing the semiconductor device, and is filled in the gap between the semiconductor device and the carrier. Therefore, the semiconductor device is automatically pulled to the target position of the carrier by the surface tension generated by the alignment solder bumps in the molten state based on the minimum surface energy principle through fusion bonding of the alignment solder bumps and the alignment bonding pads, the alignment solder bumps accurately fix the semiconductor device at the target position after cooling, drift and rotation of the semiconductor device in the plastic packaging process are prevented, and the yield of the subsequent process can be effectively improved; in view of the self-alignment capability of aligning the solder bumps, a certain degree of placement deviation is allowed when the semiconductor device is picked and placed, namely, the requirement on the placement precision of the semiconductor device is reduced, so that the speed of the semiconductor device picking and placement operation is improved, the process efficiency is further improved, and the process cost is reduced; further, protecting the active surface of the semiconductor device with the protective film in advance can release the limitation of the height of the active surface to the connection terminals and improve the protection reliability of the active surface.

### BRIEF DESCRIPTION OF THE DRAWINGS

The accompanying drawings, which are incorporated in and constitute a part of this specification, illustrate embodiments consistent with the disclosure and together with the description, serve to explain the principles of the disclosure.

In order to more clearly illustrate the embodiments of the present disclosure or the solutions in the prior technology, the drawings that are required for the description of the embodiments or the prior technology will be briefly described below, and it will be obvious to those skilled in technology that other drawings can be obtained from these drawings without inventive effort.

FIG. 1 is a schematic flow chart of a semiconductor packaging method according to an embodiment of the disclosure;

FIG. 2 is a schematic structural diagram corresponding to each step in the semiconductor packaging method shown in FIG. 1;

FIG. 3 is a flow chart illustrating another semiconductor packaging method according to an embodiment of the disclosure;

FIG. 4 is a schematic structural diagram corresponding to each manufacturing step of the semiconductor device according to the embodiment of the disclosure;

FIG. 5 is a schematic structural diagram corresponding to each preparation step of a carrier board according to an embodiment of the disclosure;

FIG. 6 is a flow chart of another semiconductor packaging method according to an embodiment of the disclosure;

FIG. 7 is a schematic structural diagram of a semiconductor device according to an embodiment of the disclosure;

FIG. 8 is a schematic structural diagram of another semiconductor device according to an embodiment of the present disclosure.

### DETAILED DESCRIPTION OF THE EMBODIMENTS

In order that the above objects, features and advantages of the present disclosure may be more clearly understood, a further description of aspects of the present disclosure will be provided below. It should be noted that, without conflict, the embodiments of the present disclosure and features in the embodiments may be combined with each other.

In the following description, numerous specific details are set forth in order to provide a thorough understanding of the present disclosure, but the present disclosure may be practiced otherwise than as described herein; it will be apparent that the embodiments in the specification are only some, but not all, embodiments of the disclosure.

In the related technology, fan-out packages typically employ a molding compound to encapsulate a single or multiple goods die from a singular wafer and to route interconnect traces from the connection pads of the die to external solder balls via a redistribution layer to achieve higher I/O density and flexible integration. In the current technical problems of Fan-out package, high-precision placement and position fixing of wafers still lack an efficient and economical method, a chip mounter with high price is generally adopted for chip mounting, and the alignment precision of the wafers depends on the precision of the chip mounter and is generally larger than ±2 μm. Often, the higher the placement accuracy of the chip mounter is, the higher the equipment cost is, and the lower the production efficiency is.

In order to solve the above technical problems, embodiments of the present disclosure provide a semiconductor packaging method, a semiconductor assembly, and an electronic device, the semiconductor packaging method including: providing a semiconductor device; the semiconductor device comprises an active surface and a passive surface which are oppositely arranged, wherein the passive surface comprises alignment bonding pads, and the active surface is provided with a protective film; alignment solder bumps corresponding to the alignment bonding pads are arranged on one side surface of the carrier; removing the protective film, and forming connecting terminals on the active surface; providing a carrier; the surface of one side of the carrier is provided with alignment solder bumps corresponding to the alignment bonding pads; the alignment solder bumps and the alignment bonding pads are basically aligned, and fusion bonding is carried out on the alignment solder bumps and the alignment bonding pads, so that the semiconductor device is accurately aligned and fixed to the carrier; forming a molding layer on one side of the carrier facing the semiconductor device; the molding layer is used for coating the semiconductor device, also covers the active surface, the connecting terminals and the surface, which is not occupied by the semiconductor device, of the surface of one side of the carrier facing the semiconductor device, and is filled in the gap between the semiconductor device and the carrier. Therefore, the semiconductor device is automatically pulled to the target position of the carrier by the surface tension generated by the alignment solder bumps in the molten state based on the minimum surface energy principle through fusion bonding of the alignment solder bumps and the alignment bonding pads, the alignment solder bumps accurately fix the semiconductor device at the target position after cooling, drift and rotation of the semiconductor device in the plastic packaging process are prevented, and the yield of the subsequent process can be effectively improved; in view of the self-alignment capability of aligning the solder bumps, a certain degree of placement deviation is allowed when the semiconductor device is picked and placed, namely, the requirement on the placement precision of the semiconductor device is reduced, so that the speed of the semiconductor device picking and placement operation is improved, the process efficiency is further improved, and the process cost is reduced; further, protecting the active surface of the semiconductor device with the protective film in advance can release the limitation of the height of the active surface to the connection terminals and improve the protection reliability of the active surface. The following describes exemplary embodiments of a semiconductor packaging method, a semiconductor assembly, and an electronic device according to embodiments of the present disclosure with reference to the accompanying drawings.

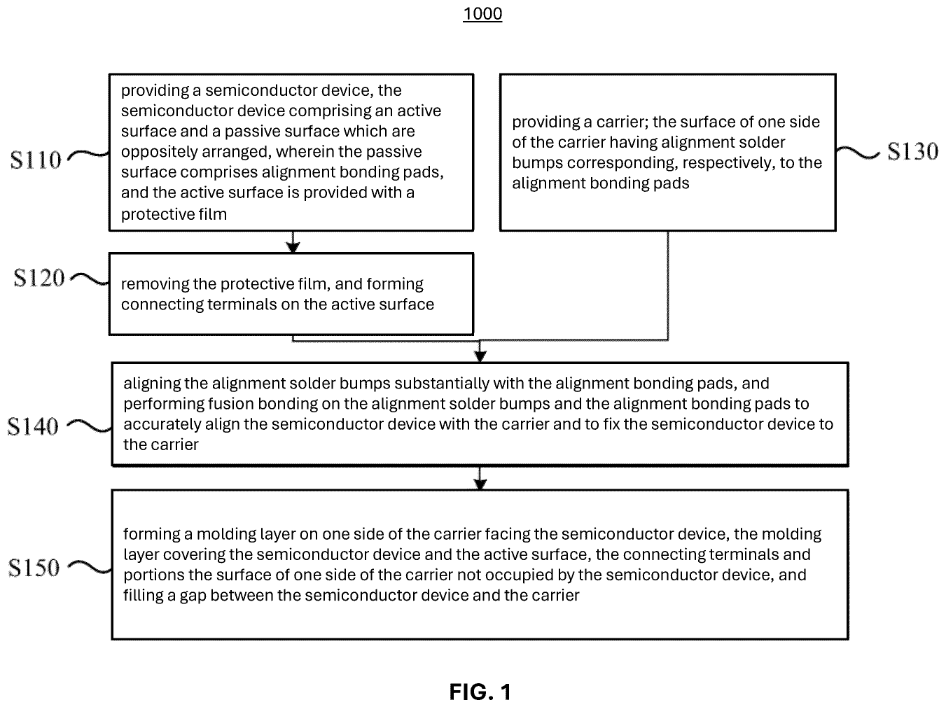

In some embodiments, as shown in FIG. 1, a flow chart of a semiconductor packaging method 1000 according to an embodiment of the disclosure is shown. Referring to FIG. 1, the semiconductor packaging method 1000 includes the steps of:

S110, providing a semiconductor device; the semiconductor device comprises an active surface and a passive surface which are oppositely arranged, the passive surface comprises alignment bonding pads, and the active surface is provided with a protective film.

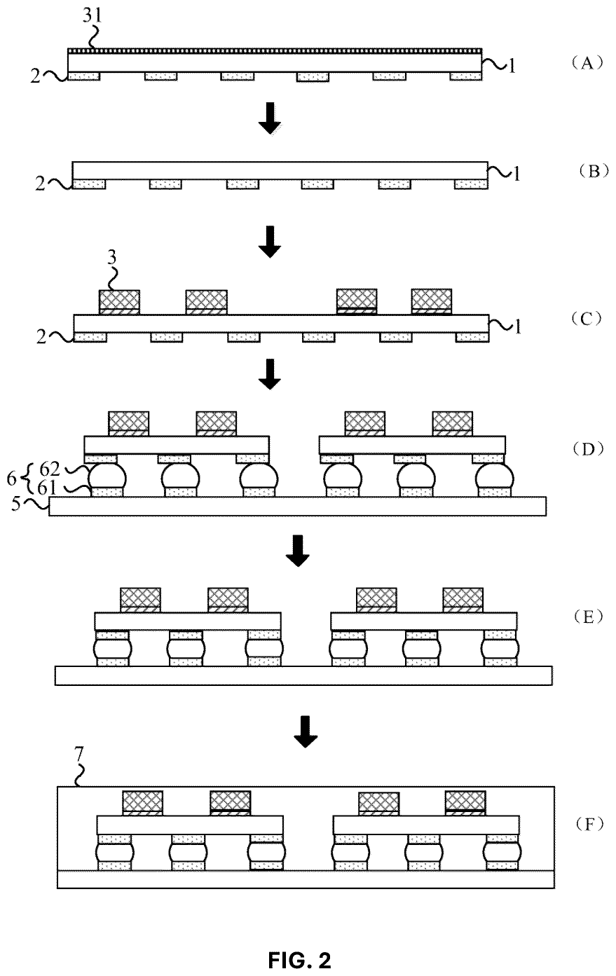

In these embodiments, the semiconductor device 1 includes, but is not limited to, a die, a chip, and a wafer. Illustratively, as shown in step (A) of FIG. 2, the semiconductor device 1 is a wafer. The semiconductor device 1 includes a passive surface provided with a protective film 31 and an active surface provided with a plurality of alignment bonding pads 2, which are disposed opposite to each other.

S120, removing the protective film, and forming connecting terminals on the active surface.

As shown in steps (B) to (C) of FIG. 2, the protective film 31 on the active surface of the semiconductor device 1 is removed, and then the connection terminals 3 is formed on the active surface of the semiconductor device 1. The connection terminals 3 are used for electrical connection with the interconnect layers and the external terminals in the subsequent steps to achieve electrical connection of the semiconductor device 1 with the external devices.

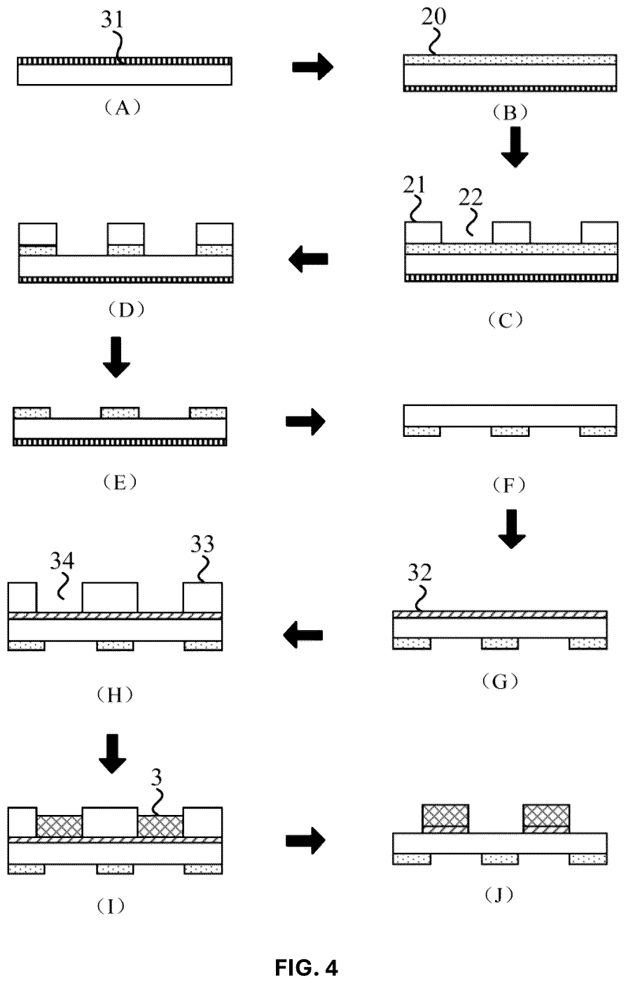

As shown in steps (F) to (J) of FIG. 4, the method for manufacturing the connection terminals 3 specifically includes: removing the protective film 31, forming a seed layer 32 on the active surface of the semiconductor device 1, coating a third photoresist layer 33 on the side, away from the semiconductor device 1, of the seed layer 32, exposing and developing the third photoresist layer 33, forming a third openings 34 in the third photoresist layer 33, and exposing the seed layer 32 at the bottom of the third openings 34; the connection terminals 3 is formed in the third openings 34, the third photoresist layer 33 and the seed layer 32 under the third photoresist layer 33 are removed, and the connection terminals 3 and the seed layer 31 under the connection terminals 3 remain on the active face of the semiconductor device 1.

In some embodiments, after forming the connection terminals on the active surface, the semiconductor packaging method further includes the steps of:

Dicing the semiconductor device.

In this embodiment, the semiconductor device 1 is an uncut wafer, and the wafer is divided into regions, each region corresponding to a die (die); the alignment bonding pads 2 are formed on the inactive surface of each region, the connection terminals 3 are formed on the active surface of each region, and then the wafer is cut, so that the obtained wafer is used for being connected with the carrier 5 with the alignment soldering bumps 62 on one side surface, and the semiconductor device 1 is a wafer or a chip and is used for being connected with the carrier 5 with the alignment soldering bumps 62. Thus, the packaging efficiency is improved. Wherein the wafer dicing process includes at least one of dicing saw, dicing blades, laser grooving, and plasma cutting processes.

S130, providing a carrier; the surface of one side of the carrier is provided with alignment solder bumps corresponding to the alignment bonding pads.

The type of the carrier 5 is not limited in the embodiments of the present disclosure, and any type of carrier known to those skilled in technology may be used, for example, the carrier 5 includes at least one of glass carriers, ceramic carriers, metal carriers, organic polymer material carriers, and silicon wafers. One side surface of the carrier 5 is provided with alignment soldering bumps 62 corresponding to the alignment bonding pads 2 one by one.

In this embodiment, S130 and S110 to S120 are parallel steps, and the execution order of the two steps is not limited.

S140, basically aligning the alignment solder bumps with the alignment bonding pads, and carrying out fusion bonding on the alignment solder bumps and the alignment bonding pads so that the semiconductor device is accurately aligned and fixed on the carrier.

As shown in steps (D)-(E) of FIG. 2, the “substantial alignment” of the alignment solder bumps 62 with the alignment bonding pads 2 means that it is included that the alignment bonding pads 2 and the alignment solder bumps 62 are respectively in contact with each other, but are not precisely centered in a direction perpendicular to the passive surface. “centered” herein generally means that the center of the alignment bonding pads 2 and the alignment solder bumps 62 are aligned in a direction perpendicular to the passive surface. “precise alignment” means a state in which a deviation between an actual position of the semiconductor device 1 on the carrier 5 and a target position is within a tolerance range in technology.

The alignment solder bumps 62 are made of solder, and the fusion soldering can be performed by using all fusion soldering methods known to those skilled in technology, including but not limited to reflow soldering, laser soldering, high frequency soldering, infrared soldering, etc.

In this step, when the semiconductor device 1 is placed on the carrier 5, the passive face of the semiconductor device 1 faces the carrier 5, the active face of the semiconductor device 1 faces away from the carrier 5, and the alignment bonding pads 2 and the alignment solder bumps 62 are in contact with each other but are not precisely centered in a direction perpendicular to the passive face of the semiconductor device 1 or the carrier 5; during the soldering process, the alignment bumps 62 melts or partially melts and wets the alignment bonding pads 2, and at this time, the alignment bumps 62 in a molten or partially molten state tends to deform and move to bring the alignment bonding pads 2 and the alignment bumps 62 close to a centered state based on the minimum surface energy principle, thereby bringing the lighter semiconductor device 1 into precise alignment to a target position on the carrier 5 (i.e., the position where the alignment bumps 62 are located). After the alignment solder bumps 62 are cooled, the semiconductor device 1 is precisely fixed at the target position on the carrier 5, so that high-strength mechanical fixation (reaching the kilogram force level) of the semiconductor device 1 and the carrier 5 is realized, the drift and rotation problems of the semiconductor device 1 on the carrier 5 in the subsequent plastic packaging process are solved, and the yield of the subsequent process is effectively improved.

After the alignment bonding pads 2 and the alignment bumps 62 are soldered, the solder structure itself formed by the soldering of the two has a certain height, so that the passive surface of the semiconductor device 1 and the carrier 5 are spaced apart to form a certain space therebetween.

It should be noted that the number of the semiconductor devices 1 in the embodiment of the present disclosure is not limited, and FIG. 2 shows only two semiconductor devices 1 fixed on the carrier 5 by way of example, and the number of the semiconductor devices 1 may be set as desired, for example, one, three, or more.

S150, forming a molding layer on one side of the carrier facing the semiconductor device; the molding layer is used for coating the semiconductor device, also covers the active surface, the connecting terminals and the surface, which is not occupied by the semiconductor device, of the surface of one side of the carrier facing the semiconductor device, and is filled in the gap between the semiconductor device and the carrier.

As shown in step (F) of FIG. 2, the molding process such as injection molding, compression molding or printing may be used to perform the molding, and the material for preparing the molding layer 7 includes a molding compound of a resin-based material (e.g., epoxy resin). The molding layer 7 and the semiconductor device 1 are located on the same side of the carrier 5, and the molding layer 7 not only covers the surface of the carrier 5 which is not occupied by the semiconductor device 1, covers the active surface and the connecting terminals, but also covers the side surface of the semiconductor device 1, and fills the gap between the passive surface of the semiconductor device 1 and the carrier 5.

According to the semiconductor packaging method provided by the embodiment of the disclosure, the alignment solder bumps 62 and the alignment bonding pads 2 are subjected to fusion bonding, the semiconductor device 1 is automatically pulled to the target position of the carrier 5 by the surface tension generated by the alignment solder bumps 62 in a fusion state based on the minimum surface energy principle, the alignment solder bumps 62 accurately fix the semiconductor device 1 at the target position after cooling, drift and rotation of the semiconductor device 1 in the plastic packaging process are prevented, and the yield of subsequent procedures can be effectively improved; in view of the self-alignment capability of the alignment solder bumps 62, a certain degree of placement deviation is allowed when the semiconductor device 1 is picked and placed, that is, the requirement on the placement accuracy of the semiconductor device 1 is reduced, so that the speed of the picking and placement operation of the semiconductor device 1 is increased, the process efficiency is further improved, and the process cost is reduced; further, protecting the active surface of the semiconductor device 1 with the protective film 31 in advance can release the restriction of the height of the active surface to the connection terminals 3 and improve the protection reliability of the active surface.

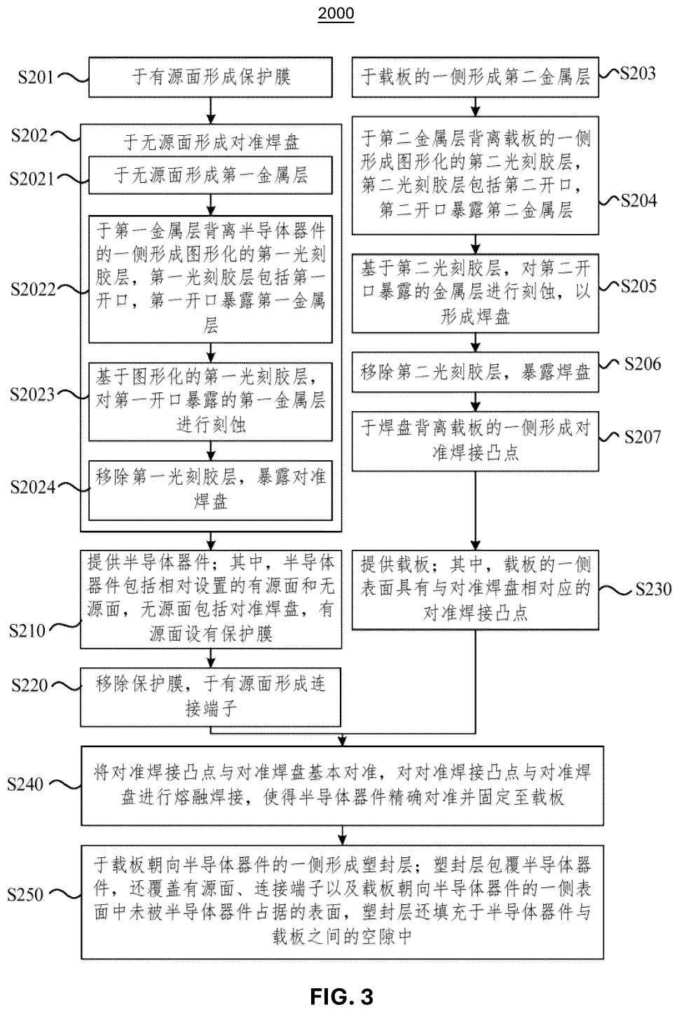

In some embodiments, as shown in FIG. 3, a semiconductor packaging method 2000 includes some or all of the steps in method 1000 and further includes the following steps, before “providing the semiconductor device:

S201 forms a protective film on the active surface.

S202, forming alignment bonding pads on the passive surface.

As shown in steps (A)-(E) in FIG. 4, a protective film 31 is formed on the active surface of the semiconductor device 1, then alignment bonding pads 2 is fabricated on the passive surface of the semiconductor device 1, the active surface is protected by the protective film, and the protective film 31 has the characteristics of chemical corrosion resistance, high temperature resistance, light transmittance and the like, so that the active surface is prevented from being damaged by processes such as exposure, chemical etching and the like used for fabricating the alignment bonding pads 2.

In some embodiments, as shown in FIG. 3, S202 “forming alignment bonding pads on a passive surface” includes the steps of:

S2021, forming a first metal layer on the passive surface.

In this step, as shown in step (B) of FIG. 4, a first metal layer 20 is formed on and covers the inactive surface of the semiconductor device 1, and the first metal layer 20 includes, but is not limited to, copper and aluminum, and further includes other metals known to those skilled in technology, which are not limited herein.

S2022, forming a patterned first photoresist layer on one side of the first metal layer, which faces away from the semiconductor device, wherein the first photoresist layer comprises second openings, and the first openings exposes the first metal layer.

In this step, as shown in step (C) in FIG. 4, a first photoresist layer 21 is coated on a surface of the first metal layer 20 facing away from the semiconductor device 1, the first photoresist layer 21 is subjected to exposure and development, and second openings 22 is formed in the first photoresist layer 21, so as to obtain a patterned first photoresist layer 21, and the bottom of the first openings 22 exposes the first metal layer 20.

The first photoresist layer 21 may be a positive photoresist, or a negative photoresist, and is not limited thereto. If the first photoresist layer 21 adopts positive photoresist, exposing the photoresist at the position corresponding to the first openings 22, dissolving the photoresist at the position during development, and forming the first openings 22 in the first photoresist layer 21; if the first photoresist layer 21 is a negative photoresist, the photoresist except the positions corresponding to the first openings 22 is exposed, and the photoresist which is not exposed is dissolved during development, i.e., the photoresist at the positions corresponding to the first openings 22 is dissolved, so that the first openings 22 are formed in the first photoresist layer 21.

S2023, etching the first metal layer exposed by the first openings based on the patterned first photoresist layer.

In this step, as shown in step (D) in FIG. 4, the first metal layer 20 exposed in the first openings 22 is etched until the first metal layer 20 is etched through and the passive surface of the semiconductor device 1 is exposed.

S2024, removing the first photoresist layer, exposing the alignment bonding pads.

In this step, as shown in step (E) in FIG. 4, the first metal layer 20 under the first photoresist layer 21 is not etched, the first photoresist layer 21 is removed, and the remaining first metal layer 20 is the alignment bonding pads 2. The shape of the alignment bonding pads 2 is affected by the shape of the patterned first photoresist layer 21.

It should be noted that the semiconductor device 1 shown in FIG. 4 is an uncut wafer, and the wafer is divided into regions, and each region corresponds to a die (die); alignment bonding pads 2 is formed on the inactive surface of each region, connection terminals 3 is formed on the active surface of each region, and then the wafer is cut to obtain a semiconductor device 1 having the connection terminals 3 and the alignment bonding pads 2, wherein the semiconductor device 1 can be used for connection with a carrier 5 having alignment solder bumps 62. Thus, the packaging efficiency is improved.

In some embodiments, as shown in FIG. 3, before the “providing carrier plate”, the semiconductor packaging method 2000 further includes the following steps:

S203, forming a second metal layer on one side of the carrier.

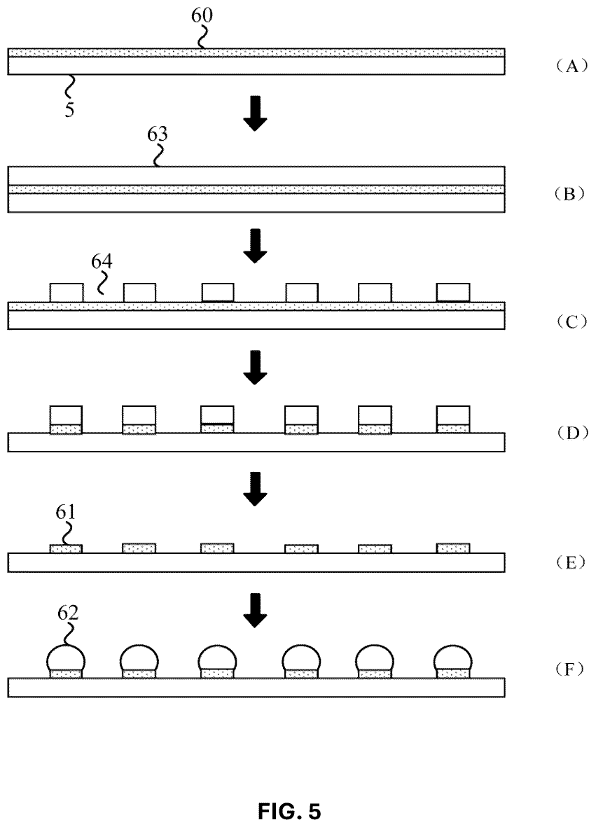

In this step, as shown in step (A) in FIG. 5, a second metal layer 60 is formed on one side of the carrier 5 and covers the surface of the carrier 5, and the second metal layer 60 includes, but is not limited to, copper and aluminum, and other metals known to those skilled in technology, which are not limited herein.

S204, forming a patterned second photoresist layer on one side of the second metal layer, which is away from the carrier, wherein the second photoresist layer comprises second openings, and the second openings exposes the second metal layer.

In this step, as shown in steps (B) and (C) in FIG. 5, a second photoresist layer 63 is coated on a side surface of the second metal layer 60 facing away from the carrier 5, the second photoresist layer 63 is exposed and developed, and second openings 64 is formed in the second photoresist layer 63, so as to obtain a patterned second photoresist layer 63, and the bottom of the second openings 64 exposes the second metal layer 60. The second photoresist layer 63 may be a positive photoresist or a negative photoresist, which is not limited herein.

S205, etching the metal layer exposed by the second openings based on the second photoresist layer to form bonding pads.

In this step, as shown in step (D) in FIG. 5, the second metal layer 60 exposed in the second openings 64 is etched until the second metal layer 60 is etched through and the carrier 5 is exposed, and the second metal layer 60 under the second photoresist layer 63 is not etched, and the remaining second metal layer 60 form the bonding pads 61.

S206, removing the second photoresist layer to expose the bonding pads.

In this step, as shown in step (E) of FIG. 5, the second photoresist layer 63 is removed, exposing the pads 61 under the second photoresist layer 63. The shape of the pads 61 is affected by the shape of the patterned second photoresist layer 63.

S207, forming alignment solder bumps on one side of the bonding pads away from the carrier.

In this step, as shown in step (F) of FIG. 5, alignment solder bumps 62 may be formed on the pads 61 by an electroplating method, a ball-mounting method, a stencil printing method, or an evaporation/sputtering method. The alignment solder bumps 62 may be spherical or columnar in shape, and are not limited thereto.

In the present embodiment, the execution order of S201 to S202 and S203 to S207 is not limited, and S201 to S202 and S203 to S207 may be executed simultaneously, or S201 to S202 and then S203 to S207 may be executed first, or S203 to S207 and then S201 to S202 may be executed first.

It should be noted that the embodiment of the present disclosure only exemplarily illustrates that the alignment bonding pads 2 and the pads 61 are fabricated by using a back etching method, but does not constitute a limitation of the semiconductor packaging method provided by the embodiment of the present disclosure. In other embodiments, other processes known to those skilled in technology may be used to fabricate the alignment bonding pads 2 and the pads 61, for example, by first covering the passive side of the semiconductor device 1 (or the surface of the side of the carrier 5) with a seed layer, then forming a patterned photoresist layer, then forming a metal layer in the openings of the photoresist layer, and removing the photoresist layer and the seed layer underneath it to complete the fabrication of the alignment bonding pads 2 (or the pads 61), which is not limited herein.

In this embodiment, S210 to S250 are the same as S110 to S150, and are specifically described in the sections S110 to S150, and are not described here again.

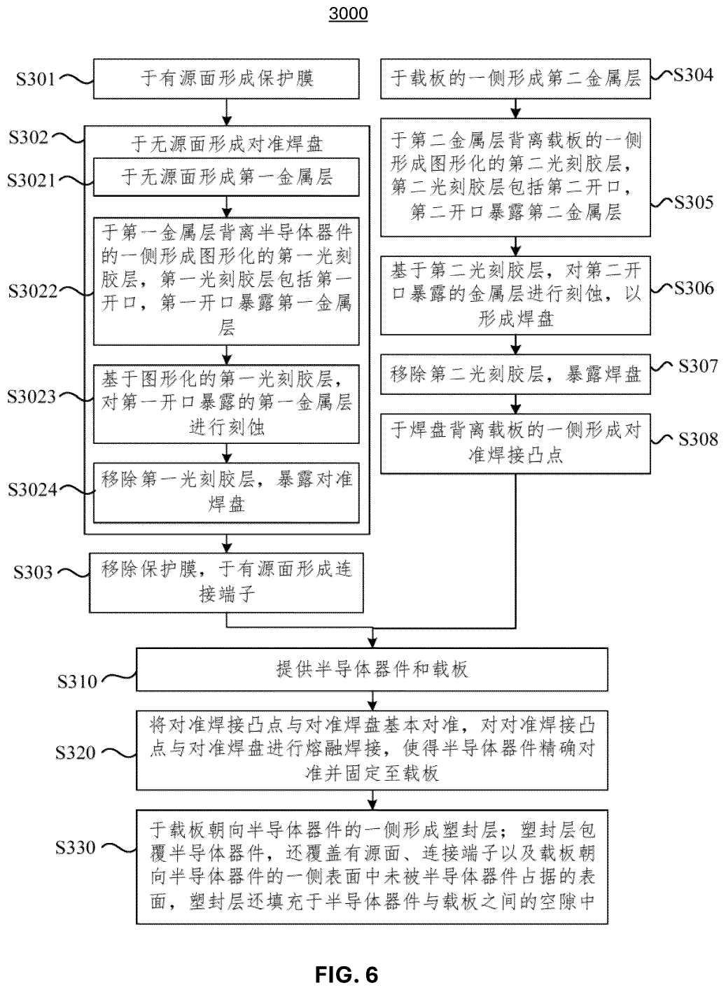

In some embodiments, as shown in FIG. 6, a semiconductor packaging method 3000 includes some or all of the steps in method 1000 and method 2000, and further includes the steps of:

S301, forming a protective film on the active surface.

S302, forming alignment bonding pads on the passive surface.

The method for fabricating the alignment bonding pads can be explained in the above-mentioned steps S2021 to S2024, which are not repeated here.

S303, removing the protective film, and forming connecting terminals on the active surface.

The steps S301 to S303 are operations performed on the wafer, and the active surface of the wafer is formed with the alignment bonding pads 2 and the active surface is formed with the connection terminals 3, and then the wafer is diced to obtain a die or chip having the active surface with the connection terminals 3 and the passive surface with the alignment bonding pads 2. After the present step is completed, step S310 is executed.

S304, forming a second metal layer on one side of the carrier.

S305, forming a patterned second photoresist layer on one side of the second metal layer, which is away from the carrier, wherein the second photoresist layer comprises second openings, and the second openings exposes the second metal layer.

S306, etching the metal layer exposed by the second openings based on the second photoresist layer to form bonding pads.

S307, removing the second photoresist layer to expose the bonding pads.

S308, forming alignment solder bumps on one side of the bonding pads, which is away from the carrier.

The steps S304 to S308 are the same as the steps S203 to S207, and will not be described here again. After S308 is completed, step S310 is performed.

S310, providing a semiconductor device and a carrier.

In the step, the semiconductor devices prepared in S301-S303 and the carriers prepared in S304-S308 are reserved; the semiconductor device comprises an active surface and a passive surface which are oppositely arranged, wherein the passive surface comprises alignment bonding pads, and the active surface is provided with connecting terminals; one side surface of the carrier is provided with alignment solder bumps corresponding to the alignment bonding pads.

S320, basically aligning the alignment solder bumps with the alignment bonding pads, and carrying out fusion bonding on the alignment solder bumps and the alignment bonding pads so that the semiconductor device is accurately aligned and fixed on the carrier.

S330, forming a molding layer on one side of the carrier facing the semiconductor device; the molding layer is used for coating the semiconductor device, also covers the active surface, the connecting terminals and the surface, which is not occupied by the semiconductor device, of the surface of one side of the carrier facing the semiconductor device, and is filled in the gap between the semiconductor device and the carrier.

In the present embodiment, the execution order of S301 to S303 and S304 to S308 is not limited, and S301 to S303 and S304 to S308 may be executed simultaneously, or S301 to S303 and S304 to S308 may be executed first, or S304 to S308 and S301 to S303 may be executed first.

In some embodiments, “fusion soldering the alignment solder bumps to the alignment bonding pads” includes the steps of:

Heating the alignment solder bumps so that the alignment solder bumps are at least partially in a molten state;

Bonding the alignment solder bumps which are at least partially in a molten state with the alignment bonding pads.

In this embodiment, the bonding may be performed by any fusion bonding method known to those skilled in technology, including, but not limited to reflow bonding, laser bonding, high-frequency bonding, infrared bonding, and the like. The alignment solder bumps 62 are heated to a melting point, and part of the alignment solder bumps 62 are in a molten state or all of the alignment solder bumps 62 are in a molten state, and surface tension generated by the alignment solder bumps 62 in the molten state automatically pulls the semiconductor device 1 down to a target position on the carrier 5 (i.e., the position where the alignment solder bumps 62 are located), and after the alignment solder bumps 62 are cooled, the semiconductor device 1 is precisely fixed at the target position on the carrier 5, so that self-alignment of the semiconductor device 1 is realized, and the requirement on the placement accuracy of the semiconductor device 1 is reduced.

In some embodiments, after “forming a molding layer on a side of the carrier toward the semiconductor device”, the semiconductor packaging method further includes the steps of:

The carrier is removed using at least one of lift-off, etching, ablation, and grinding processes.

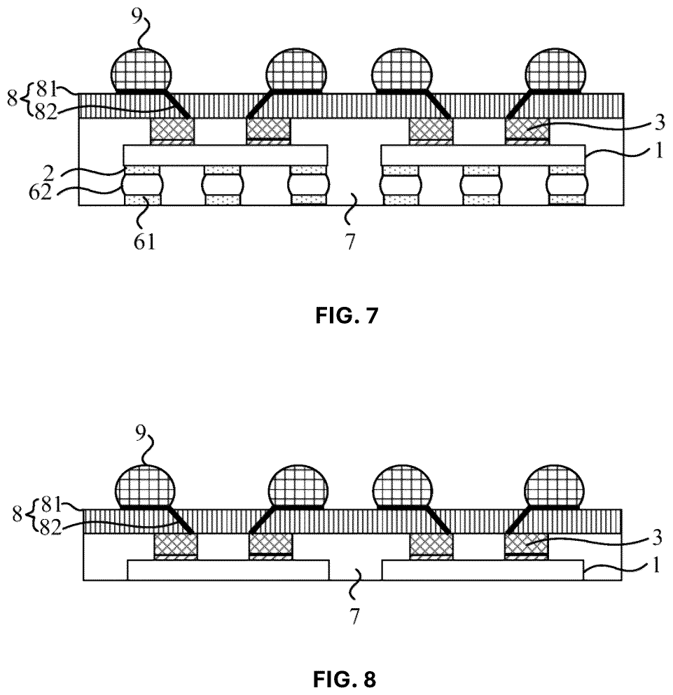

In this embodiment, other processes besides stripping, etching, ablation and grinding processes can be used to remove the carrier 5, which are not limited herein, as will be appreciated by those skilled in technology. As shown in FIG. 7, after the carrier 5 is removed, a side surface of the molding layer 7 near the alignment solder bumps 62 is exposed.

In some embodiments, after removing the carrier, the semiconductor packaging method further comprises the steps of:

Thinning the surface of the molding layer, which is close to one side aligned with the solder bumps.

In this embodiment, when the carrier 5 is removed or after the carrier 5 is removed, the surface of the molding layer 7 near the alignment soldering bumps 62 is thinned by a process such as debonding, etching, ablation or grinding, so as to remove at least a part of the structure except the passive surface of the semiconductor device 1, thereby further reducing the thickness of the final semiconductor assembly.

The thickness of the thinned semiconductor device 1 is not limited in this embodiment, and as shown in FIG. 8, the thinned semiconductor device 1 can be thinned to the passive surface, and all structures except the passive surface of the semiconductor device 1, that is, the alignment bonding pads 2, the alignment solder bumps 62, the pads 61, and the corresponding molding layer 7 are removed; it is also possible to thin down to any position outside the passive plane and to remove part of the structure outside the passive plane of the semiconductor device 1, for example to remove only the pads 61 and the corresponding molding layer 7 or to remove the alignment solder bumps 62 and the corresponding molding layer 7.

In some embodiments, after forming the molding layer, the semiconductor packaging method further comprises the steps of:

Thinning the surface of the molding layer, which is close to the active surface and one side of the connecting terminals, so as to expose the connecting terminals;

Forming an interconnection layer and external terminals on the surface of one side of the molding layer, which is exposed from the connection terminals; the connection terminals are electrically connected with the external terminals through the interconnection layer.

In this embodiment, the molding layer 7 is thinned by at least one of chemical mechanical polishing (Chemical Mechanical Polishing, CMP) grinding, etching and ablating processes until the connection terminals 3 are exposed. As shown in FIG. 7 or 8, an interconnection layer 8 is formed on a side of the connection terminals 3 facing away from the semiconductor device, and external terminals 9 is formed on a side of the interconnection layer 8 facing away from the connection terminals 3. The interconnect layer 8 is electrically connected to the connection terminals 3 and the external terminals 9, and the external terminals 9 are used to connect external devices, so that the electrical connection of the semiconductor device 1 to external devices is achieved.

The interconnect layer 8 may be fabricated using all processes known to those skilled in technology and will not be described in detail herein. The interconnect layer 8 includes a redistribution layer 82 and an insulating layer 81, and the connection terminals 3 is electrically connected to the external terminals 9 through the redistribution layer 82.

It should be noted that FIGS. 7 to 8 only exemplarily illustrate that the external terminals 9 are solder balls, but do not constitute a limitation of the semiconductor packaging method provided by the embodiment of the present disclosure. In other embodiments, the external terminals 9 may be provided as pads or solder columns, which are not limited herein.

On the basis of the foregoing embodiments, the embodiments of the present disclosure further provide a semiconductor assembly, where the semiconductor assembly is packaged by any one of the foregoing semiconductor packaging methods, and has corresponding beneficial effects, and in order to avoid repetitive description, no further description is given here.

In some embodiments, as shown in step (F) of FIG. 2, the semiconductor assembly includes: at least one semiconductor device 1, the active surface of the semiconductor device 1 is provided with connecting terminals 3, and the passive surface of the semiconductor device 1 is provided with alignment bonding pads 2; a carrier 5 having alignment solder bumps 62 provided on one side surface thereof, the alignment solder bumps 62 being precisely aligned with the alignment bonding pads 2 so that the semiconductor device 1 is precisely aligned and fixed to the carrier 5; the molding layer 7 is positioned on one side of the carrier 5 facing the semiconductor device 1, covers the surface of the carrier 5 not occupied by the semiconductor device 1 and covers the active surface and the connecting terminals 3 of the semiconductor device 1, and the molding layer 7 is also filled in the gap between the semiconductor device 1 and the carrier 5.

In some embodiments, as shown in FIG. 7 or 8, the semiconductor assembly further comprises: an interconnect layer 8 and external terminals 9, the interconnect layer 8 being located on a side of the connection terminals 3 facing away from the semiconductor device 1, the external terminals 9 being located on a side of the interconnect layer 8 facing away from the connection terminals 3; the interconnect layer 8 includes a redistribution layer 82 and an insulating layer 81, the redistribution layer 82 being electrically connected to the connection terminals 3 and the external terminals 9, the external terminals 9 being for connection to an external device. So arranged, an electrical connection of the semiconductor device 3 with external devices is achieved.

In some embodiments, as shown in FIG. 7, the carrier 5 in the semiconductor assembly is removed by at least one of lift-off, etching, ablation, and grinding processes.

In some embodiments, as shown in FIG. 8, the surface of the molding layer 7 near the alignment bumps is thinned, and at least part of the structure other than the passive surface of the semiconductor device 1 is removed to further reduce the thickness of the semiconductor assembly.

In this embodiment, when the carrier 5 is removed or after the carrier 5 is removed, the surface of the molding layer 7 near the alignment soldering bumps 62 is thinned by a process such as debonding, etching, ablation or grinding, so as to remove at least a part of the structure except the passive surface of the semiconductor device 1, thereby further reducing the thickness of the final semiconductor assembly.

The thickness of the thinned semiconductor device 1 is not limited in this embodiment, and as shown in FIG. 8, the thinned semiconductor device 1 can be thinned to the passive surface, and all structures except the passive surface of the semiconductor device 1, that is, the alignment bonding pads 2, the alignment solder bumps 62, the pads 61, and the corresponding molding layer 7 are removed; it is also possible to thin down to any position outside the passive plane and to remove part of the structure outside the passive plane of the semiconductor device 1, for example to remove only the pads 61 and the corresponding molding layer 7 or to remove the alignment solder bumps 62 and the corresponding molding layer 7.

On the basis of the foregoing implementation manner, the embodiment of the present disclosure further provides an electronic device, where the electronic device includes: the semiconductor device has the corresponding beneficial effects, and to avoid repeated description, the description is omitted.

It should be noted that in this document, relational terms such as “first” and “second” and the like are used solely to distinguish one entity or action from another entity or action without necessarily requiring or implying any actual relationship or order between such entities or actions. Moreover, the terms “comprises,” “comprising,” or any other variation thereof, are intended to cover a non-exclusive inclusion, such that a process, method, material, or equipment that comprises a list of elements does not include only those elements but may include other elements not expressly listed or inherent to such process, method, material, or apparatus. Without further limitation, an element defined by the phrase “comprising one . . . ” does not exclude the presence of other like elements in a process, method, material, or equipment that comprises the element.

The foregoing is merely a specific embodiment of the disclosure to enable one skilled in technology to understand or practice the disclosure. Various modifications to these embodiments will be readily apparent to those skilled in technology, and the generic principles defined herein may be applied to other embodiments without departing from the spirit or scope of the disclosure. Thus, the present disclosure is not intended to be limited to the embodiments shown and described herein but is to be accorded the widest scope consistent with the principles and novel features disclosed herein.

1. A semiconductor packaging method, comprising:
providing a semiconductor device, the semiconductor device having an active surface and a passive surface opposite to the active surface, wherein the passive surface has alignment bonding pads, and the active surface is provided with a protective film;
removing the protective film, and forming connecting terminals on the active surface;
providing a carrier having alignment solder bumps formed on a surface of one side of the carrier, the alignment solder bumps corresponding, respectively, to the alignment bonding pads;
aligning the alignment solder bumps substantially with the alignment bonding pads, and performing fusion bonding on the alignment solder bumps and the alignment bonding pads to further align the semiconductor device more accurately with the carrier and to fix the semiconductor device to the carrier;
forming a molding layer on one side of the carrier facing the semiconductor device, the molding layer covering the semiconductor device and the active surface, the connecting terminals and portions the surface of one side of the carrier not occupied by the semiconductor device, and filling a gap between the semiconductor device and the carrier.

2. The semiconductor packaging method according to claim 1, characterized in that before the providing of the semiconductor device, the semiconductor packaging method further comprises:
forming the protective film on the active surface;
and forming the alignment bonding pads on the passive surface.

3. The semiconductor packaging method of claim 2, wherein forming alignment bonding pads on the passive surface comprises:
forming a first metal layer on the passive surface;
forming a patterned first photoresist layer on one side of the first metal layer away from the semiconductor device, the first photoresist layer having first openings exposing the first metal layer;
etching the first metal layer exposed by the first openings based on the patterned first photoresist layer to form first alignment pads under the photoresist layer; and
removing the first photoresist layer to expose the first alignment pads.

4. The semiconductor packaging method according to claim 1, wherein before the providing of the carrier, the semiconductor packaging method further comprises:
forming a second metal layer on one side of the carrier;
forming a patterned second photoresist layer on one side of the second metal layer away from the carrier; the second photoresist layer comprises second openings, the second openings exposing the second metal layer;
etching the metal layer exposed by the second openings based on the second photoresist to form a bonding pads;
removing the second photoresist to expose the bonding pads;
and forming alignment solder bumps on one side of the bonding pads, which is away from the carrier.

5. The method of semiconductor packaging of claim 1, wherein performing the fusion bonding on the alignment solder bumps and the alignment bonding pads includes:
heating the alignment solder bumps so that the alignment solder bumps is at least partially in a molten state;
and bonding the alignment solder bumps which are at least partially in a molten state with the alignment bonding pads.

6. The semiconductor packaging method of claim 1, further comprising:
removing the carrier using at least one of lift-off, etching, ablation, and grinding processes.

7. The semiconductor packaging method of claim 6, wherein after removing the carrier, the semiconductor packaging method further comprises:
thinning the surface of the molding layer, which is close to one side of the alignment solder bumps.

8. The semiconductor packaging method of claim 1, further comprising:
thinning the surface of the molding layer, which is close to the active surface and one side of the connecting terminals, so as to expose the connecting terminals;
forming an interconnection layer and external terminals on the surface of one side of the molding layer, which is exposed from the connection terminals; the connection terminals are electrically connected with the external terminals through the interconnection layer.

9. A semiconductor assembly made using the semiconductor packaging method according to claim 1.

10. An electronic device comprising the semiconductor assembly of claim 9.
